(19) United States
(12) Patent Application Publication
(10) Pub. No.: US 2013/0283001 A1
(43) Pub. Date: Oct. 24, 2013

(54) SEMICONDUCTOR DEVICE THAT BURST-OUTPUTS READ DATA

(71) Applicant: ELPIDA MEMORY, INC., Tokyo (JP)

(72) Inventor: Toru Ishikawa, Tokyo (JP)

(73) Assignee: Elpida Memory, Inc., Tokyo (JP)

(21) Appl. No.: 13/844,918

(22) Filed: Mar. 16, 2013

(30) Foreign Application Priority Data
Apr. 24, 2012 (JP) 2012-098347

(51) Int. Cl. G11C 7/22

(52) U.S. Cl. CPC G11C 7/22
USPC 711/167

(57) ABSTRACT

Disclosed herein is a device that includes: a data terminal; a plurality of memory banks; and a control circuit configured to control a data transfer between the data terminal and the memory banks. The control circuit is configured to set a read latency in response to a burst length.

### BACKGROUND OF THE INVENTION

1. Field of the Invention

The present invention relates to a semiconductor device and an information processing system including the same. In particular, the present invention relates to a semiconductor device that burst-outputs a plurality of read data in response to a read command, and an information processing system including the same.

2. Description of Related Art

A semiconductor memory device, such as a Dynamic Random Access Memory (DRAM), includes a memory cell array typically divided into a plurality of memory banks (see Japanese Patent Application Laid-Open Nos. 2000-82287, 2011-165298, and 2011-175563). Memory banks are capable of individual command execution. Memory banks can thus be accessed in a nonexclusive manner.

For example, a semiconductor memory device described in Japanese Patent Application Laid-Open No. 2000-82287 automatically executes “bank interleaving” to alternately access two memory banks. Read data is thereby burst-output a plurality of times in successive manner. A semiconductor memory device described in Japanese Patent Application Laid-Open No. 2011-165298 outputs read data from banks 0 to 7 through data terminals DQ0 to DQ7, respectively. Data stored in the banks 0 to 7 in a distributed manner can thus be efficiently output. A semiconductor memory device described in Japanese Patent Application Laid-Open No. 2011-175563 includes memory banks that are further divided into a plurality of blocks each. Blocks to be accessed and the output order can be selected based on a burst length select signal, a block select signal, etc.

In the semiconductor memory devices described in Japanese Patent Application Laid-Open Nos. 2000-82287, 2011-165298, and 2011-175563, a plurality of read data read in response to a single read command are continuously output from a data terminal or terminals in succession. Consequently, the speed of reading the read data from the memory banks in response to a read command is designed to allow continuous burst output.

A semiconductor memory device of so-called wide I/O type having a large number of data terminals has recently been proposed. Such a type of semiconductor memory device reads a large number of bits of read data from memory banks in response to a read command. For example, if the burst length is four bits and the number of data terminals is 32, the number of bits of read data to be read from the memory banks in response to a read command is 128 (=4×32). If the number of data terminals is 64, the number is 256 (=4×64).

When the number of data terminals is 64, sense amplifiers twice as many as when the number of data terminals is 32 need to be simultaneously activated, providing that the memory banks have the same array configuration. For example, suppose the number of data terminals is 32 and the number of sense amplifiers simultaneously activated is 2 Kbytes. If the number of data terminals is 64, then the number of sense amplifiers simultaneously activated doubles to be 4 Kbytes. This increases the amount of peak current as well as power supply noise.

The array configuration may be changed to reduce the number of sense amplifiers to be simultaneously activated. Even if the number of data terminals is 64, the array configuration can be changed to keep the number of data terminals to be simultaneously activated the same as when the number of data terminals is 32. However, such a configuration increases the number of lines of data interconnection formed on the array, with a significant increase in the chip area.

Under the circumstances, a technology for suppressing an increase of the number of sense amplifiers simultaneously activated without increasing the chip area has been desired. Such a technology has been desired not only of semiconductor memory devices such as a DRAM, but also of all semiconductor devices having a plurality of memory banks and information processing systems using the same.

### SUMMARY

In one embodiment, there is provided a semiconductor device that includes: a command terminal configured to receive a read command; a data terminal; a plurality of memory banks; a data interconnection coupled in common to the memory banks; and a control circuit configured to respond to the read command to perform a first read operation in which first and second read data sets are serially transferred from one of the memory banks to the data interconnection. Each of the first and second read data sets includes a plurality of read data. The first and second data sets appear on the data interconnection respectively at first and second timings. The semiconductor device further includes an output circuit configured receive the first and second read data sets from the data interconnection, to start outputting the first read data set to the data terminal at a third timing and to start outputting the second read data set to the data terminal at a fourth timing. A first period of time intervenes between the first and third timings and a second period of time intervenes between the second and fourth timings. The second period of time is different from the first period of time.

According to one aspect of the present invention, there is provided a device that includes: a data terminal; a plurality of memory banks; and a control circuit configured to control a data transfer between the data terminal and the memory banks. The control circuit is configured to set a read latency in response to a burst length.

### BRIEF DESCRIPTION OF THE DRAWINGS

FIG. 1 is a block diagram of the semiconductor device according to a first embodiment of the present invention;

FIG. 2 is a timing chart illustrating a read operation of the semiconductor device according to the first embodiment of the present invention, showing the case where burst length is four bits;

FIG. 3 is a timing chart illustrating a read operation of the semiconductor device according to the first embodiment of the present invention, showing the case where burst length is two bits;

FIG. 4 is a timing chart illustrating a write operation of the semiconductor device according to the first embodiment of the present invention, showing the case where burst length is four bits;

FIG. 5 is a block diagram of the semiconductor device according to a second embodiment of the present invention;

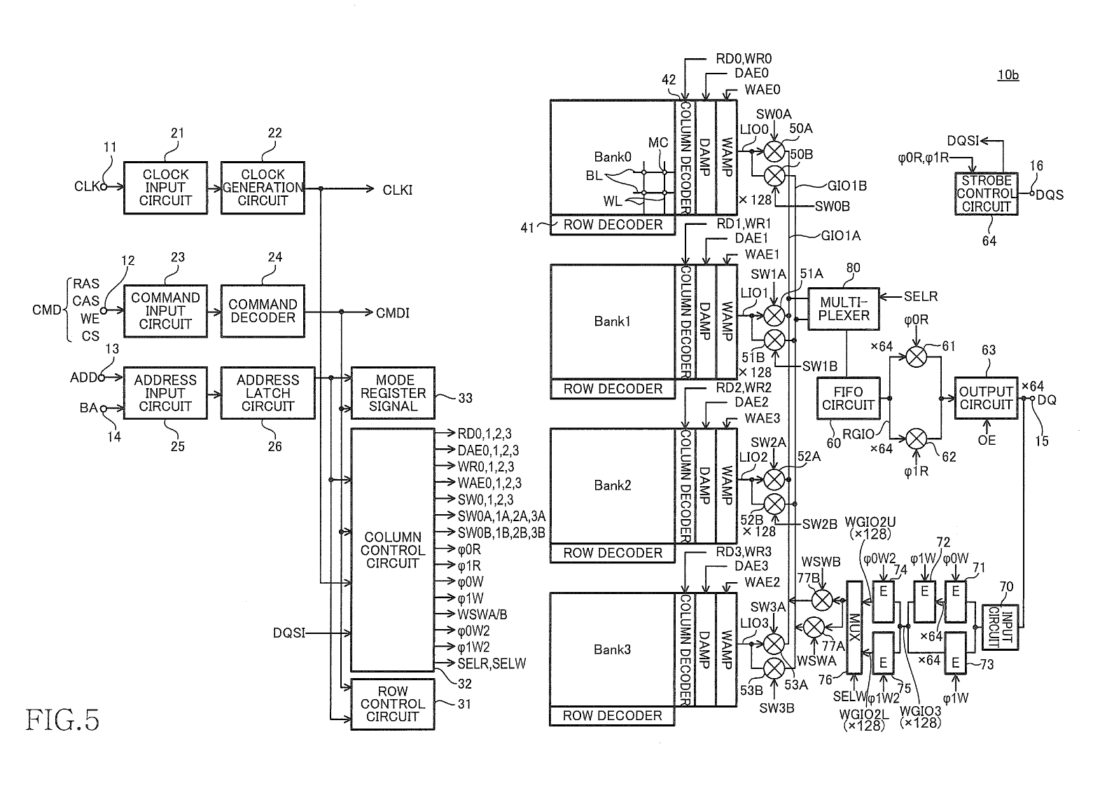

FIG. 6 is a timing chart illustrating a read operation of the semiconductor device according to the second embodiment of the present invention, showing the case where burst length is four bits;

FIG. 7 is a timing chart illustrating a write operation of the semiconductor device according to the second embodiment of the present invention, showing the case where burst length is four bits;

FIG. 8 is a block diagram of the information processing system according to a third embodiment of the present invention;

FIG. 9 is a block diagram of the information processing system according to a fourth embodiment of the present invention; and

FIG. 10 is a block diagram of the information processing system according to a fifth embodiment of the present invention.

### DETAILED DESCRIPTION OF THE EMBODIMENTS

Preferred embodiments of the present invention will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

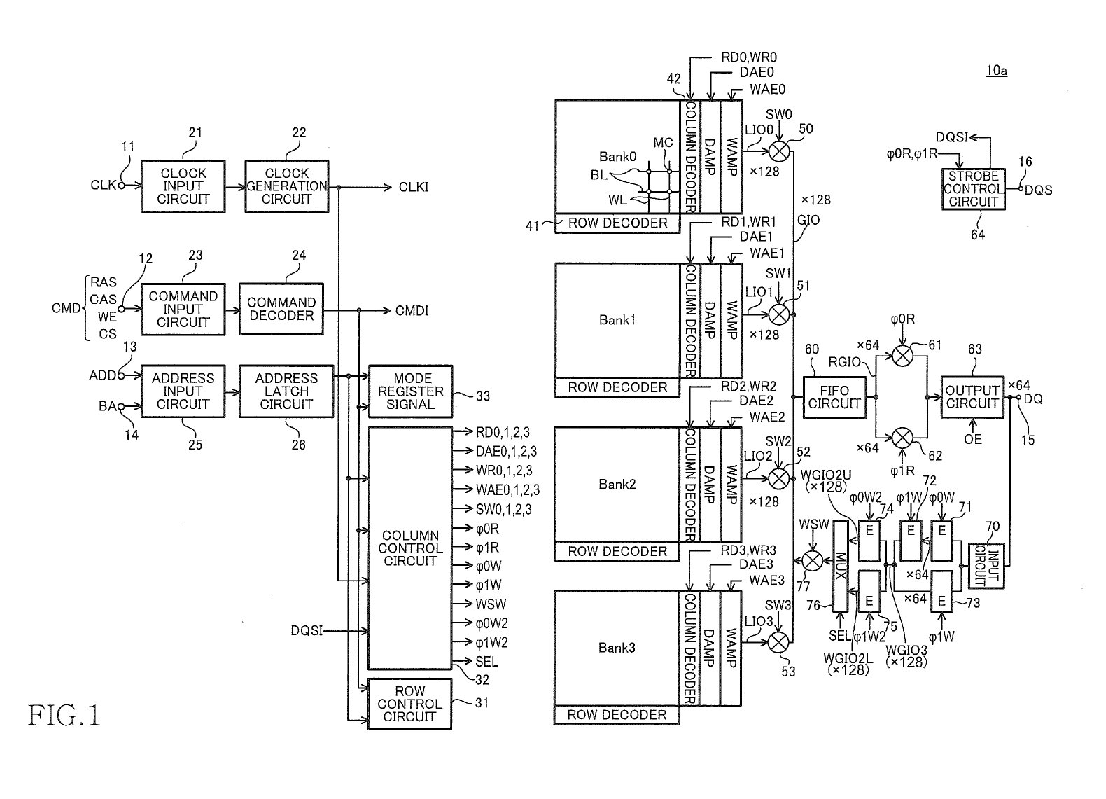

Referring now to FIG. 1, the semiconductor device 10a according to the first embodiment of the present invention is a DRAM, which is integrated as a single semiconductor chip. As shown in FIG. 1, the semiconductor device 10a according to the present embodiment has external terminals including a clock terminal 11, a command terminal 12, an address terminal 13, a bank address terminal 14, data terminals 15 and a strobe terminal 16. The external terminals also include power supply terminals and a calibration terminal, which are not directly related to the gist of the present invention and a description thereof will thus be omitted. In the present embodiment, the number of data terminals 15 is 64. In other words, 64 bits of data is input or output at a time.

The clock terminal 11 is supplied with an external clock signal CLK from outside the semiconductor device 10a. The external clock signal CLK input to the clock terminal 11 is supplied to a clock generation circuit 22 through a clock input circuit 21. The clock generation circuit 22 generates an internal clock signal CLKI based on the external clock signal CLK. The internal clock signal CLKI is supplied to various circuit blocks including a row control circuit 31, a column control circuit 32, and a mode register 33 to be described later, and is used as a timing signal for defining operation timing of the semiconductor device 10a.

The command terminal 12 is supplied with external command signals CMD from outside the semiconductor device 10a. The external command signals CMD include a row address strobe signal RAS, a column address strobe signal CAS, a write enable signal WE, and a chip select signal CS. Command types are expressed by combinations of such signals. The external command signals CMD input to the command terminal 12 are supplied to a command decoder 24 through a command input circuit 23. The command decoder 24 generates an internal command signal CMDI based on the combination of the external command signals CMD. The internal command signal CMDI is supplied to the row control circuit 31, the column control circuit 32, the mode register signal 33 to be described later, etc.

The address terminal 13 and the bank address terminal 14 are terminals to which an address signal ADD and a bank address signal BA are supplied from outside the semiconductor device 10a, respectively. The address signal ADD and the bank address BA input to the terminals 13 and 14 are supplied to an address latch circuit 26 through an address input circuit 25. The address signal ADD and the bank address signal BA retained in the address latch circuit 26 are supplied to the row control circuit 31, the column control circuit 32, or the mode register 33 based on the internal command signal CMDI.

Specifically, if the internal command signal CMDI indicates a row access, the address signal ADD and the bank address signal BA retained in the address latch circuit 26 are supplied to the row control circuit 31. The row control circuit 31 selects a memory bank indicated by the bank address BA and supply the address signal ADD to a row decoder 41 corresponding to the selected memory bank. The address signal ADD supplied to the row decoder 41 may be referred to as a row address. The row decoder 41 selects a word line WL in the memory bank based on the address signal ADD (row address). The internal command signal CMDI indicates a row access when the external command signals CMD indicate an active command.

If the internal command signal CMDI indicates a column access, the address signal ADD and the bank address BA retained in the address latch circuit 26 are supplied to the column control circuit 32. The column control circuit 32 selects a memory bank indicated by the bank address signal BA and supply the address signal ADD to a column decoder 42 corresponding to the selected memory bank. The address signal ADD supplied to the column decoder 42 may be referred to as a column address. The column decoder 42 selects bit lines BL in the memory bank based on the address signal ADD (column address). The internal command signal CMDI indicates a column access when the external command signals CMD indicate a read command or a write command.

If the external command signals CMD indicate a read command, the column control circuit 32 activates any one of read signals RD0 to RD3 and any one of enable signals DAE0 to DAE3 based on the bank address signal BA. If the external command signals CMD indicate a write command, the column control circuit 32 activates any one of write signals WR0 to WR3 and any one of enable signals WAE0 to WAE3 based on the bank address signal BA.

Consequently, when an active command and a read command are issued in that order and a row address and a column address are input in synchronization with the respective commands, data can be read from the memory cells MC designated by such addresses. When an active command and a write command are issued in that order and a row address and a column address are input in synchronization with the respective commands, data can be written into the memory cells MC designated by such addresses.

If the internal command signal CMDI indicates mode register setting, the address signal ADD (mode signal) retained in the address latch circuit 26 is supplied to the mode register 33. The mode register 33 is a circuit in which various mode signals indicating operation modes of the semiconductor device 10a are set. When the internal command signal CMDI indicates mode register setting, the bank address signal BA selects a plurality of registers constituting the mode register 33.

As shown in FIG. 1, the semiconductor device 10a according to the present embodiment includes four memory banks Bank0 to Bank3. The memory banks are capable of individual command execution. The memory banks can thus be accessed in a nonexclusive manner. In the present invention, the number of memory banks is not limited in particular. For example, eight memory banks may be included.

The memory banks Bank0 to Bank3 each include a row decoder 41 and a column decoder 42. The memory banks Bank0 to Bank3 each include a plurality of word lines WL and a plurality of bit lines BL, at intersections of which are arranged memory cells MC. As described above, when the row decoder 41 selects a word line WL and the column decoder 42 selects bit lines BL, the memory cells MC arranged at the intersections can be accessed. In a read operation, the operation timing of the column decoder 42 is controlled by the corresponding read signal RD0, RD1, RD2, or RD3. In a write operation, the operation timing of the column decoder 42 is controlled by the corresponding write signal WR0, WR1, WR2, or WR3.

In a read operation, when a corresponding read signal RD0, RD1, RD2, or RD3 is activated, read data selected by the column address read from the memory bank by a row access is supplied to a data amplifier DAMP. The data amplifiers DAMP are activated by the corresponding enable signals DAE0 to DAE3, and function to further amplify selected read data. The read data amplified by the data amplifiers DAMP is transferred to corresponding local I/O interconnections LIO0 to LI03.

In the present embodiment, the number of memory cells MC selected by a single row access is, though not limited to, 2 Kbytes. Of these, 128 memory cells MC are selected by a column access. In other words, when a row decoder 41 selects a word line WL, 2 Kbytes of memory cells MC are connected to not-shown sense amplifiers and read data is amplified by the sense amplifiers. The corresponding column decoder 42 selects 128 bits of read data from among the 2 Kbytes of read data, and transfers the 128 bits of read data to corresponding local I/O interconnections LIO0, LIO1, LIO2, or LIO3. In the present specification, a plurality of read data that are simultaneously read out from a memory bank may be referred to as a “read data set”.

The 128 bits of read data transferred to the local I/O interconnections LIO0, LIO1, LIO2, or L103 is transferred to a global I/O interconnection GIO through a corresponding switch circuit 50, 51, 52, or 53. The switch circuits 50 to 53 are controlled by respective switch control signals SW0 to SW3 supplied from the column control circuit 32.

As shown in FIG. 1, the global I/O interconnection GIO includes signal lines that are allocated to the four memory banks Bank0 to Bank3 in common. The global I/O interconnection GIO has a data width of 128 bits. The 128 bits of read data transferred to the global I/O interconnection is transferred to a global I/O interconnection RGIO in 64 bits twice by a FIFO circuit 60. Two switch circuits 61 and 62 are connected to the global I/O interconnection RGIO in parallel, and controlled by respective switch control signals φ0R and φ1R. The switch control signals φ0R and φ1R are supplied from the column control circuit 32 in a read operation. As a result, the 128 bits of read data is serially converted into 64 bits×2 and supplied to an output circuit 63.

The output circuit 63 is activated based on an enable signal OE supplied from the column control circuit 32 in a read operation. Consequently, 64 bits of read data is output from the data terminals 15 twice. The detailed operation timing in a read operation will be described later.

Now, in a write operation, 64 bits of write data is input from outside to the 64 data terminals 15 twice. The 64 bits of write data is supplied to latch circuits 71 to 75 through an input circuit 70. The input circuit 70 is activated based on an enable signal IE supplied from the column control circuit 32 in a write operation.

As shown in FIG. 1, the latch circuits 71 and 73 are connected in parallel. The latch circuits 71 and 72 are connected in series. The latch circuit 71 is controlled by a latch control signal φ0W. The latch circuits 72 and 73 are controlled by a latch control signal φ1W. The latch control signals φ0W and φ1W are supplied from the column control circuit 32 in a write operation. As a result, two 64 bits of write data are parallel-converted into 128 bits of data and supplied to a global I/O interconnection WGI3.

The 128-bit write data that are supplied to the global I/O interconnection WGIO3 are supplied to latch circuits 74 and 75, which are connected in parallel. The latch circuit 74 is a circuit that transfers the write data on the global I/O interconnection WGIO3 to the global I/O interconnection WGIO2U. The latch circuit 74 is controlled by a latch control signal φ0W2. The latch circuit 75 is a circuit that transfers the write data on the global I/O interconnection WGIO3 to the global I/O interconnection WGIO2L. The latch circuit 75 is controlled by a latch control signal φ1W2. The latch control signals φ0W2 and φ1W2, too, are supplied from the column control circuit 32 at the time of a write operation. The global I/O interconnection WGIO2U and WGIO2L are connected to a multiplexer 76. On the basis of a selection signal SEL that is supplied from the column control circuit 32, data supplied from the global I/O interconnection WGIO2U or WGIO2L are transferred to a global I/O interconnection GIO via a switch circuit 77. At the time of a write operation, the switch circuit 77 is controlled by a switch control signal WSW, which is supplied from the column control circuit 32.

The 128 bits of write data transferred to the global I/O interconnection GIO is transferred to any one of the local I/O interconnections LIO0 to LI03 through the corresponding one of the switch circuits 50 to 53. The 128 bits of write data transferred to any one of the local I/O interconnections LIO0 to LI03 is amplified by a write amplifier WAMP activated by the corresponding one of the enable signals WAE0 to WAE3. The write data amplified by the write amplifier WAMP is written to selected memory cells MC when the corresponding one of the write signals WR0 to WR3 is activated. The detailed operation timing in a write operation will also be described later.

The strobe terminal 16 is connected to a strobe control circuit 64. The strobe control circuit 64 generates a strobe signal DQS based on switch control signals φ0R and φ1R at the time of a read operation, and outputs the strobe signal DQS from the strobe terminal 16. At the time of a write operation, the strobe control circuit 64 receives a strobe signal DQS that is input into the strobe terminal 16, and generates an internal strobe signal DQSI on the basis of the strobe signal DQS. The internal strobe signal DQSI is supplied to the column control circuit 32, and is used as a timing signal that defines generation timings of various latch control signals (φ0W and other latch control signals) required for a write operation.

Next, the operation of the semiconductor device 10a according to the present embodiment will be described.

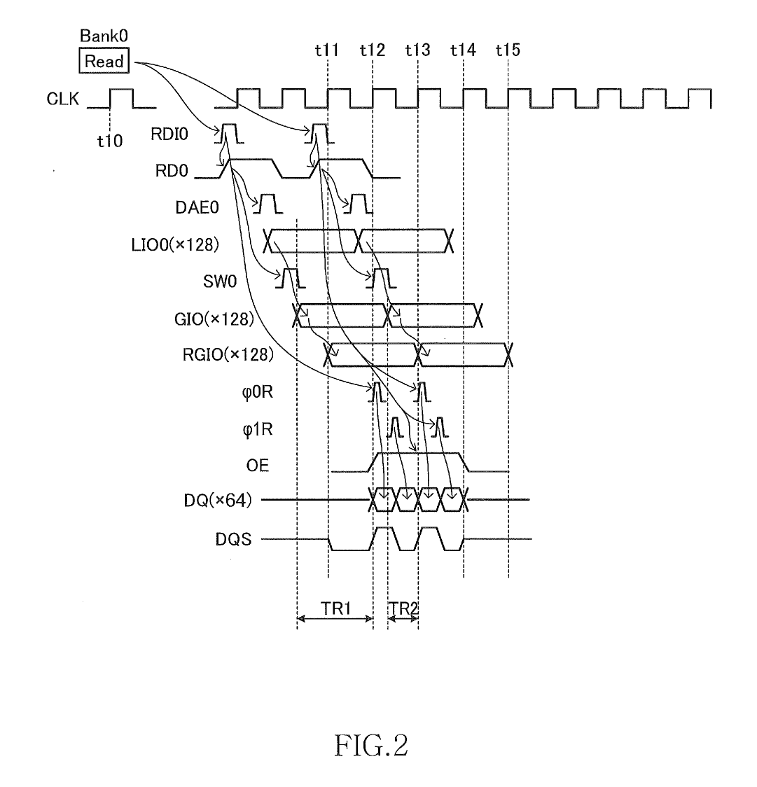

A read operation of the semiconductor device 10a according to the present embodiment where burst length is four bits is explained with reference to FIG. 2. In the present specification, the state in which the burst length is set to four bits may be referred to as a first operation mode.

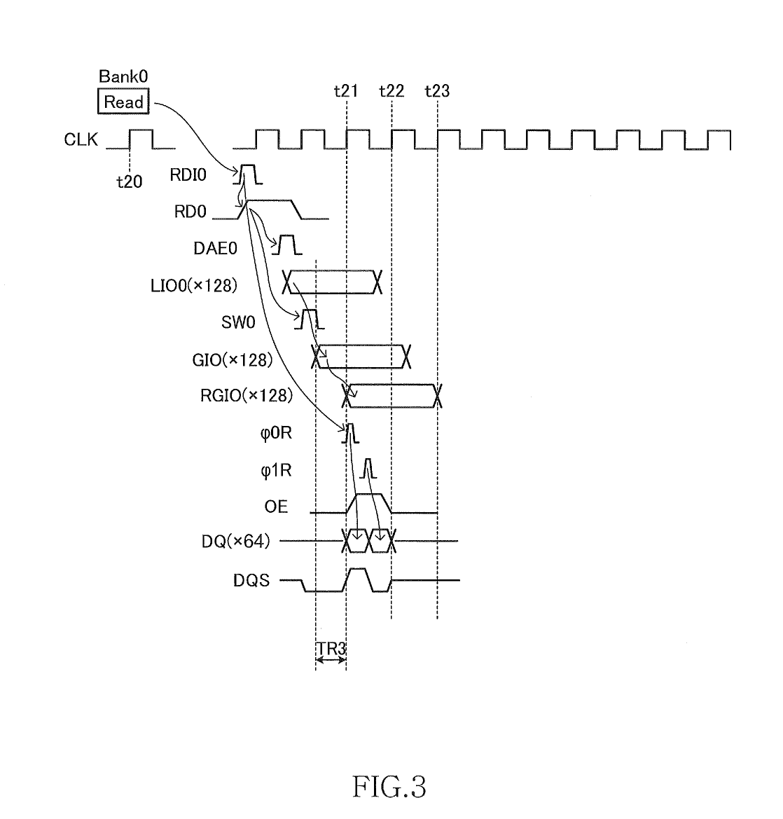

As described above, in the present embodiment, the number of data terminals 15 is 64. Consequently, 256 bits (=64×4) of read data is read from a memory bank in response to a single read command Read. In FIG. 2, the memory bank Bank0 is assumed to have selected a predetermined word line WL according to an active command supplied from outside in advance. In other words, the memory bank Bank0 shall be activated in advance. Similarly, in FIGS. 3, 4, 6 and 7 to be seen below, memory banks for a read command Read or a write command Write to be supplied to shall be activated in advance.

In the example shown in FIG. 2, at time t10, a read command Read, which specifies a memory bank Bank0, is issued. As shown in FIG. 2, in response to the read command Read at time t10, a read timing signal RDI0 is activated twice at intervals of two clock cycles. The read timing signal RDI0 is an internal signal of the column control circuit 32, and is used to define a timing that serves as a reference for the read operation of the memory bank Bank0. As the read timing signal RDI0 is activated, a read signal RD0 then becomes activated. Furthermore, on the basis of the read signal RD0, an enable signal DAE0 becomes activated. Incidentally, the reason why the read timing signal RDI0 becomes activated twice is because the burst length is set to four bits. If the burst length is set to two bits as described later, the read timing signal RDI0 is activated only one time. Although not shown in the diagrams, the read timing signal RDI0 is activated four times if the burst length is set to eight bits.

The first activation of the read signal RD0 and the enable signal DAE0 is intended to read the first two bits of read data to be burst-output from each of the data terminals. The second activation of the read signal RD0 and the enable signal DAE0 is intended to read the second two bits of read data to be burst-output from each of the data terminals.

When the enable signal DAE0 is activated, read data amplified by the data amplifier DAMP is transferred to the local I/O interconnection LIO0. As described above, the local I/O interconnection LIO0 has a data width of 128 bits. In other words, 256 bits of read data to be read from the memory bank in response to a single read command Read is output to the local I/O interconnection LIO0 in 128 bits twice. The read data output to the local I/O interconnection LIO0 is transferred to the global I/O interconnection GIO in two separate transactions in synchronization with the switch control signal SW0.

The read data that are transferred to the global I/O interconnection GIO are transferred to the global I/O interconnection RGIO via a FIFO circuit 60. As shown in FIG. 2, on the global I/O interconnection RGIO, the 128-bit read data set that is the first data set to have been read appears during the period of time t11 to t13. The 128-bit read data set that is the second data set to have been read appears during the period of time t13 to t15. During the period of time t11 to t13, Each of the switch control signals φ0R and φ1R is activated once at a corresponding timing. During the period of time t13 to t15, each of the switch control signals φ0R and φ1R is activated once at a corresponding timing.

The first activation of the switch control signals φ0R and φ1R defines the timing to output the first 128 bits of read data set read from the memory bank Bank0. The second activation of the switch control signals φ0R and 91R defines the timing to output the second 128 bits of read data set read from the memory bank Bank0.

In this case, the first activation of the switch control signals φ0R and φ1R is carried out in the latter half of the period t11 to t13. The second activation of the switch control signals φ0R and φ1R is carried out in the first half of the period t13 to t15. More specifically, the first activation of the switch control signal φ0R is carried out immediately after time t12. The first activation of the switch control signal φ1R is carried out 0.5 clock cycles after the activation of the switch control signal φ0R. The second activation of the switch control signal φ0R is carried out immediately after time t13. The second activation of the switch control signal φ1R is carried out 0.5 clock cycles after the activation of the switch control signal φ0R.

Therefore, during the period of two clock cycles from the period t12 to t14, the burst outputting of the read data DQ is seamlessly carried out from the data terminals 15 in 0.5 clock cycles. That is, the 256-bit read data that are read from the memory banks are output in two stages, i.e. two sets of 128-bit data are output at intervals of two clock cycles. However, the period TR1 (first period) that is required to start a serial outputting process of the first read data set after the first read data set is read to the global I/O interconnection GIO is set longer than the period TR2 (second period). The period TR2 (second period) is a period that is required to start a serial outputting process of the second read data set after the second read data set is read to the global I/O interconnection GIO. As a result, the read data DQ can be output in bursts.

According to the present embodiment, the difference between the period TR1 and the period TR2 is set to one clock cycle, which is equal to the period required to finish the serial burst outputting process of the 128-bit read data set that is the first data set to have been read after the start of the serial burst outputting process. Therefore, immediately after the burst outputting process of the 128-bit read data set that is the first data set to have been read is finished, it is possible to seamlessly start the burst outputting process of the 128-bit read data set that is the second data set to have been read. In other words, the period from the time when the last read data contained in the first read data set are output to the time when the first read data contained in the second read data set are output is equal to the period from the time when predetermined read data contained in a certain read data set are output to the time when the next read data contained in the read data set are output.

As shown in FIG. 2, during the burst outputting of the read data DQ, the clocking of the strobe signal DQS is carried out. Therefore, a control device (not shown) that is connected to the semiconductor device 10a is able to properly receive the 4-bit read data DQ that are output in bursts.

In that manner, according to the present embodiment, a difference is provided between the period TR1 and the period TR2. Therefore, without an increase in the reading speed of the read data from the memory banks, the read data DQ can be seamlessly output in bursts. As a result, without changing the configuration of the array or increasing the number of sense amplifiers that are simultaneously activated, the read data DQ can be output in bursts.

A read operation of the semiconductor device 10a according to the present embodiment where burst length is two bits is explained with reference to FIG. 3. In the present specification, the state in which the burst length is set to two bits may be referred to as a second operation mode.

The switching of burst length may be carried out by changing a setting value of the mode register 33, or may be dynamically carried out by using a signal supplied to any one of the terminals. As an example of the dynamic switching of burst length, the following method is available: a method of using, as a selection signal, an address bit Al2 that is input at the time of column access, and setting the burst length to four bits when the logic level thereof is a low level, or setting the burst length to two bits when the logic level thereof is a high level.

In the example shown in FIG. 3, at time t20, a read command Read, which specifies a memory bank Bank0, is issued. In the present example, since the burst length is set to two bits, the read timing signal RDI0 is activated only one time after the read command Read is issued. The operation that starts in response to the activation of the read timing signal RDI0 is basically the same as the operation described in FIG. 2. However, the timings at which the switch control signals φ0R and φ1R are activated are different from those in FIG. 2.

First, the 128-bit read data set that is transferred to the global I/O interconnection GIO is transferred to the global I/O interconnection RGIO via the FIFO circuit 60. As shown in FIG. 3, on the global I/O interconnection RGIO, the 128-bit read data set appears during the period of time t21 to t23. During the period of time t21 to t23, the switch control signals φ0R and φ1R each are activated once. In response to the activation, the read data DQ are output in bursts.

In this case, the activation of the switch control signals φ0R and φ1R is carried out in the first half of the period t21 to t23. More specifically, the activation of the switch control signal φ0R is carried out immediately after time t21. The activation of the switch control signal φ1R is carried out 0.5 clock cycles after the activation of the switch control signal φ0R. Therefore, during the period of one clock cycle from t21 to t22, the burst outputting of the read data DQ is carried out. As shown in FIG. 3, when the burst length is set to two bits, the period TR3 (third period) that is required to start a serial outputting process of the read data set after the read data set is read to the global I/O interconnection GIO is so set as to be equal to the above period TR2 (second period). Therefore, when the burst length is set to two bits, it is possible to reduce the read latency, or the period from the time when the read command Read is issued until the time when the first read data are output, compared with the case where the burst length is set to four bits.

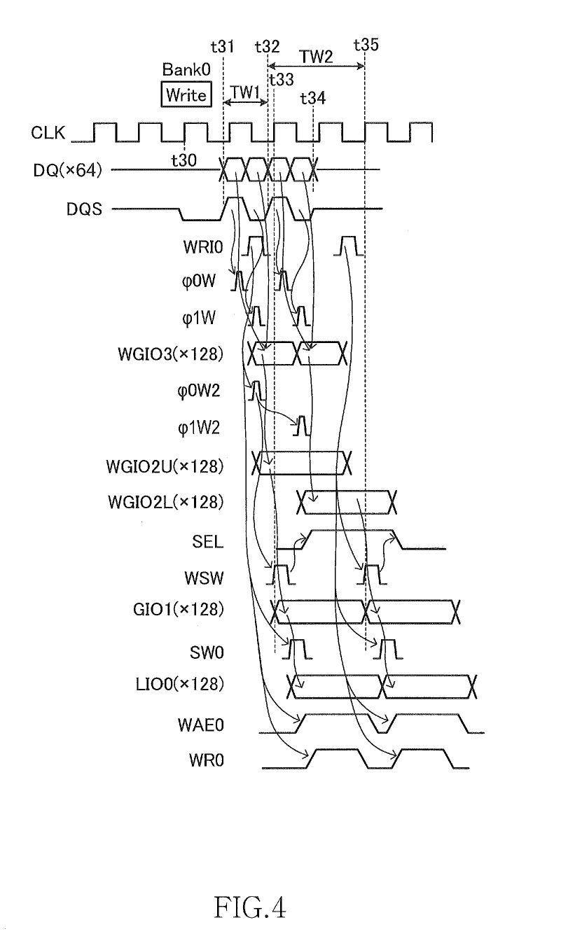

A write operation of the semiconductor device 10a according to the present embodiment where burst length is four bits is explained with reference to FIG. 4.

In the example shown in FIG. 4, at time t30, a write command Write, which specifies a memory bank Bank0, is issued. During the period of two clock cycles from t31 to t34, the burst inputting of the write data DQ is seamlessly carried out from the 64 data terminals 15 in 0.5 clock cycles. As shown in FIG. 4, in response to the write command Write at time t30, a write timing signal WRI0 is activated twice at intervals of two clock cycles. The write timing signal WRI0 is an internal signal of the column control circuit 32, and is used to define a timing that serves as a reference for the write operation of the memory bank Bank0. After the write timing signal WRI0 becomes activated, the latch control signals φ0W2, φ1W2, WSW, and SW0, the enable signal WAE0, and the write signal WR0 are sequentially activated.

During the period t31 to t34 when the write data DQ are input in bursts, the clocking of the strobe signal DQS, which is supplied from a control device, is carried out. As the clocking of the strobe signal DQS is performed, the latch control signals φ0W and φ1W are activated in synchronization with the clocking. In this case, the first activation of the latch control signals φ0W and φ1W defines a timing for capturing the 128-bit write data that should be the first write data to be written into the memory bank Bank0. The second activation of the latch control signals φ0W and φ1W defines a timing for capturing the 128-bit write data that should be the second write data to be written into the memory bank Bank0. In that manner, a plurality of write data that are written into the memory bank at once may be referred to as a “write data set.”

As a result, on the global I/O interconnection WGIO3, the first-half 128-bit write data set, which should be written into the memory bank Bank0, and the latter-half 128-bit write data set sequentially appear at intervals of one clock cycle. The 128-bit write data sets that are transferred to the global I/O interconnection WGIO3 are transferred respectively to the global I/O interconnections WGIO2U and WGIO2L via the latch circuits 74 and 75. The write data on the global I/O interconnection WGIO2U are transferred to the global I/O interconnection GIO in response to a first activation of a switch control signal WSW during a period of time when the selection signal SEL is at a low level. The write data on the global I/O interconnection WGIO2L are transferred to the global I/O interconnection GIO in response to a second activation of the switch control signal WSW during a period of time when the selection signal SEL is at a high level.

In this case, the first activation of the switch control signal WSW is carried out in the first half of the period during which the write data appear on the global I/O interconnection WGIO2U. The second activation of the switch control signal WSW is carried out in the latter half of the period during which the write data appear on the global I/O interconnection WGIO2L. More specifically, the first activation of the switch control signal WSW is carried out at time t33 in synchronization with a rising edge of a clock signal CLK. The second activation of the switch control signal WSW is carried out at time t35 in synchronization with a rising edge of the clock signal CLK. The period from t33 to t35 is two clock cycles. In other words, the period TW2 (fifth period) from time t32 when the third bit of burst data is input to time t35 when the switch control signal WSW is activated for the second time is so set as to be one clock cycle longer than the period TW1 (fourth period) from time t31 when the first burst data are input to time t33 when the switch control signal WSW is activated for the first time

Therefore, into the memory bank Bank0, the 128-bit write data set is written in two stages at intervals of two clock cycles. That is, the 256-bit write data DQ are input into the data terminal 15 in the following manner: two sets of 128-bit write data DQ are input at intervals of one clock cycle. However, the intervals are increased from one clock cycle to two clock cycles when the write data DQ are transferred to the memory bank Bank0. As a result, it is possible to properly write the write data DQ, which are input in bursts, into the memory bank Bank0.

In that manner, according to the present embodiment, a difference is provided between the period TW1 and the period TW2. Therefore, without an increase in the writing speed of the write data into the memory banks, the write data DQ can be seamlessly input in bursts. As a result, without changing the configuration of the array or increasing the number of sense amplifiers that are simultaneously activated, the write data DQ can be input in bursts.

What is not shown in the diagrams is a write operation that is performed when the burst length is two bits. However, the write operation is the same as that described in FIG. 4 except that an operation is not carried out for third and four bits of write data that are input in bursts. Accordingly, the write latency, or the period from the time when the write command Write is issued until the time when the first write data are input, is not changed.

The second embodiment of the present invention will be explained.

The semiconductor device 10b according to the second embodiment of the present invention differs from the semiconductor device 10a according to the first embodiment in including two groups of global I/O interconnection GIO. One of the groups of global I/O interconnection GIOA is connected to local I/O interconnection LIO0 to LI03 through switch circuits 50A to 53A. The other global I/O interconnection GIOB is connected to the local I/O interconnection LIO0 to LIO3 through switch circuits 50B to 53B. The switch circuits 50A to 53A are controlled by switch control signals SW0A to SW3A, respectively. The switch circuits 50B to 53B are controlled by switch control signals SW0B to SW3B, respectively.

The two groups of global I/O interconnection GIOA and GIOB are connected to a FIFO circuit 60 through a multiplexer 80. The multiplexer 80 is supplied with a select signal SELR from the column control circuit 32, and connects either one of the groups of global I/O interconnection GIOA and GIOB to the FIFO circuit 60 based on the select signal SEL. an output nodes of the multiplexer 76 is connected to global I/O interconnection GIOA through a switch circuit 77A, and connected to global I/O interconnection GIOB through a switch circuit 77B. The switch circuits 77A and 77B are controlled by switch control signals WSWA and WSWB, respectively.

In other respects, the semiconductor device 10b has the same configuration as that of the semiconductor device 10a according to the first embodiment. The same components are therefore designated by the same reference symbols and overlap description is here omitted.

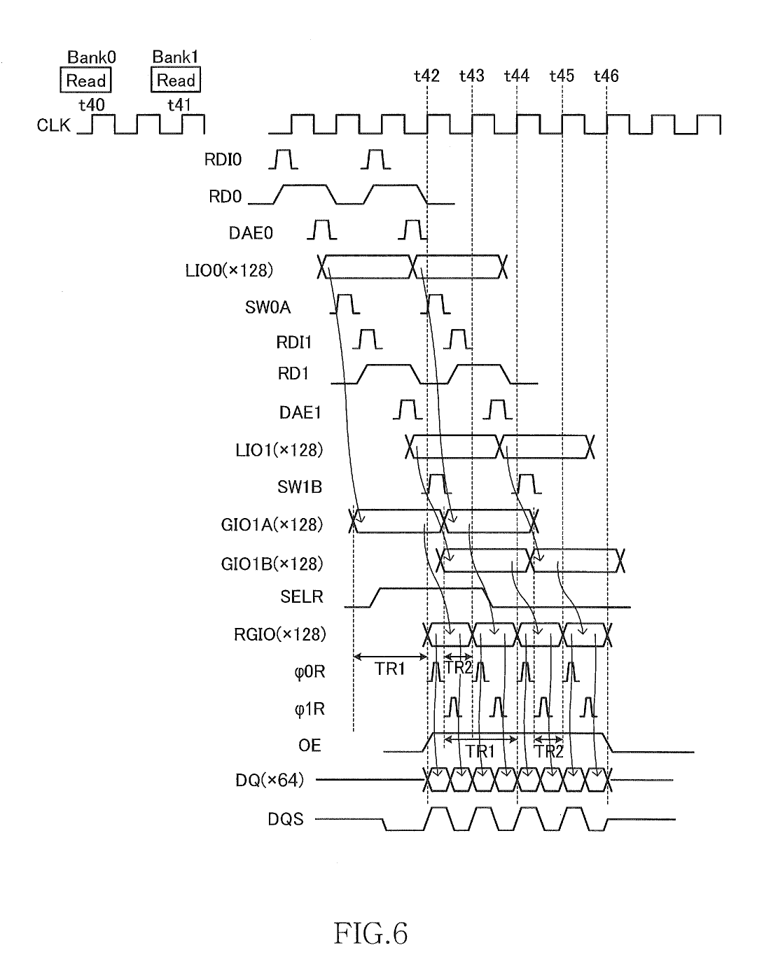

An read operation of the semiconductor device 10b according to the present embodiment where burst length is four bits is explained with reference to FIG. 6.

In the example shown in FIG. 6, a read command Read designated for the memory bank Bank0 is issued at time t40. A read command Read designated for the memory bank Bank1 is issued two clock cycle later at time t41. The operations in response to such read commands Read are basically the same as described with reference to FIG. 2. In the present embodiment, the read data read from the memory bank Bank0 is transferred to the global I/O interconnection GIOA through the switch circuit 50A. The read data read from the memory bank Bank1 is transferred to the global I/O interconnection GIOB through the switch circuit 51B. After the read command Read that specifies the memory bank Bank1 is issued, the read timing signal RDI1 is activated twice at intervals of two clock cycles. The read timing signal RDI1 is an internal signal of the column control circuit 32, and is used to define a timing that serves as a reference for the read operation of the memory bank Bank1.

The select signal SELR is clocked at every two clock cycles, whereby the pieces of read data transferred to the global I/O interconnection GIOA and GIOB are successively transferred to the FIFO circuit 60 through the multiplexer 80.

More specifically, the read data that are read to the global I/O interconnection GIOA in two stages from the memory bank Bank0 are sequentially transferred to the global I/O interconnection RGIO during a period of time when the selection signal SELR is at a high level. The read data that are read to the global I/O interconnection GIOB in two stages from the memory bank Bank1 are sequentially transferred to the global I/O interconnection RGIO during a period of time when the selection signal SELR is at a low level. In this manner, the read data on the global I/O interconnection RGIO are switched during the period t42 to t46 in one clock cycle.

The subsequent operation is the same as that described in FIG. 2. The read data are output in bursts as the switch control signals φ0R and φ1R are sequentially activated. In this case, the period required to start a serial outputting process of the first read data set after the first read data set is read to the global I/O interconnections GIOA and GIOB is equal to the above TR1. The period required to start a serial outputting process of the second read data set after the second read data set is read to the global I/O interconnections GIOA and GIOB is equal to the above TR2.

In that manner, according to the present embodiment, the two global I/O interconnections GIO are provided. Therefore, even when the read commands Read are consecutively input, the read data can be output in bursts.

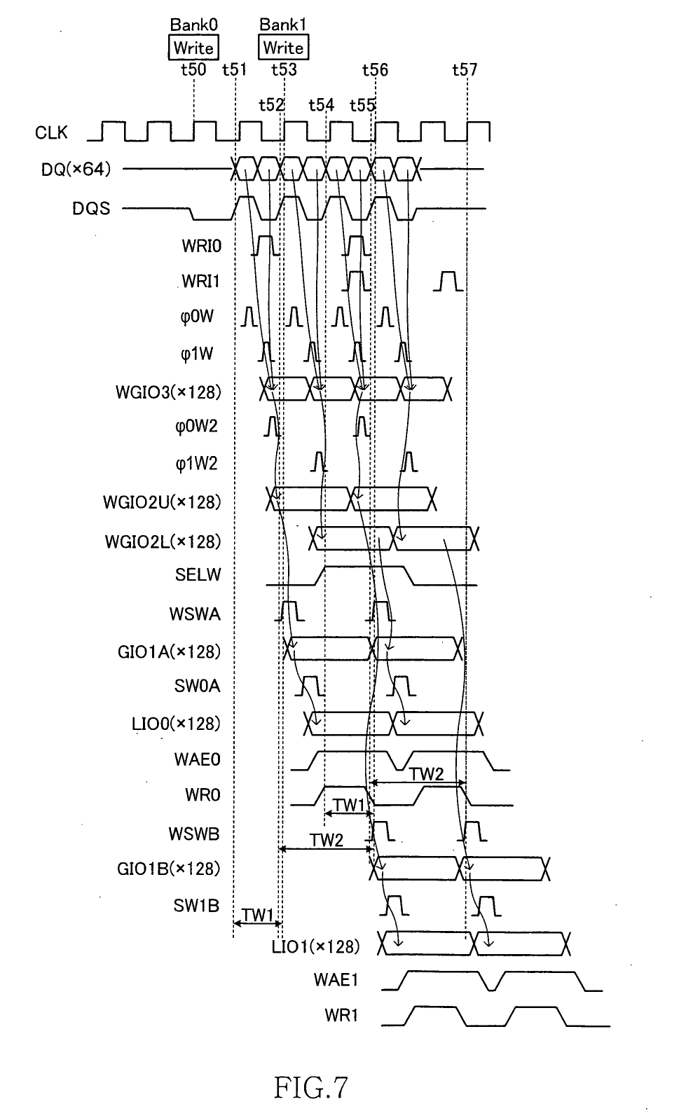

An write operation of the semiconductor device 10b according to the present embodiment where burst length is four bits is explained with reference to FIG. 7.

In the example shown in FIG. 7, at time t50, a write command Write, which specifies a memory bank Bank0, is issued. Two clock cycles later, or at time t53, a write command Write, which specifies a memory bank Bank1, is issued. After the issuing of a read command Read that specifies the memory bank Bank1, the write timing signal WRI1 is activated twice at intervals of two clock cycles. The write timing signal WRI1 is an internal signal of the column control circuit 32, and is used to define a timing that serves as a reference for the write operation of the memory bank Bank1.

The operation that starts in response to the write commands Write is basically the same as that described in FIG. 4. However, according to the present embodiment, the write data that should be written into the memory bank Bank0 are transferred to the global I/O interconnection GIOA via the switch circuit 77A, and the write data that should be written into the memory bank Bank1 are transferred to the global I/O interconnection GIOB via the switch circuit 775.

More specifically, the first activation of the switch control signal WSWA is carried out at time t53. The second activation of the switch control signal WSWA and the first activation of the switch control signal WSWB are carried out at time t56. The second activation of the switch control signal WSWB is carried out at time t57. The period from t53 to t56 is two clock cycles. The period from t56 to t57 is two clock cycles.

The period from time t51 when the first burst data are input to time t53 when the switch control signal WSWA is activated for the first time is equal to the above TW1. The period from time t52 when the third bit of burst data is input to time t56 when the switch control signal WSWA is activated for the second time is equal to the above TW2. Similarly, the period from time t54 when the fifth bit of burst data is input to time t56 when the switch control signal WSWB is activated for the first time is equal to the above TW1. The period from time t55 when the seventh bit of burst data is input to time t57 when the switch control signal WSWB is activated for the second time is equal to the above TW2.

In that manner, while the write data on the global I/O interconnection WGIO3 are switched at intervals of one clock cycle, the 128-bit write data set is written in two stages into the memory banks Bank0 and Bank1 at intervals of two clock cycles.

In that manner, according to the present embodiment, the two global I/O interconnections GIO are provided. Therefore, even when the write commands Write are consecutively input, the write data can be input in bursts.

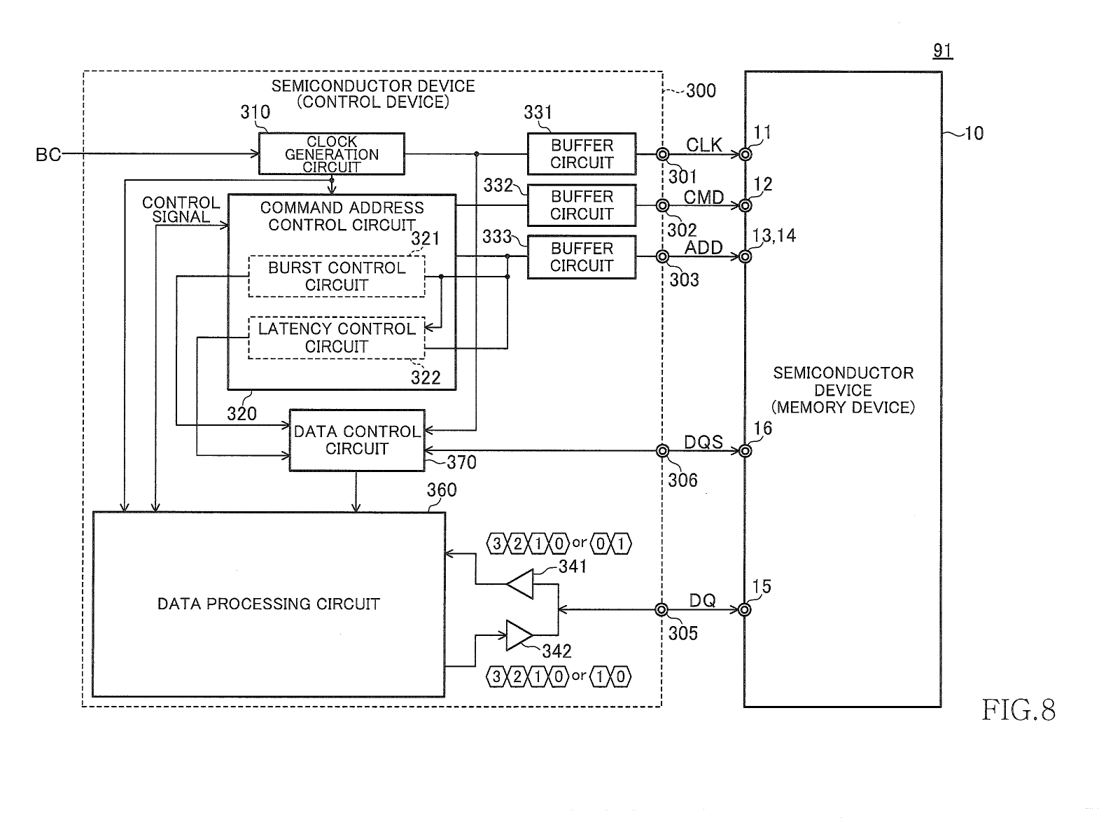

The third embodiment of the present invention will be explained with reference to FIG. 8.

The information processing system 91 shown in FIG. 8 includes a semiconductor device 300 which functions as a control device, and a semiconductor device 10 which functions as a memory device. The semiconductor devices 10a or 10b according to the foregoing first or second embodiments may be used as the semiconductor device 10. The semiconductor device 300 as a control device is integrated as a semiconductor chip separate from the semiconductor device 10 as a memory device. The semiconductor device 300 issues the foregoing various commands (read command and write command) to the semiconductor device 10, and transmits and receives read data and write data to/from the semiconductor device 10.

As shown in FIG. 8, the semiconductor device 300 as a control device includes a clock generation circuit 310 which generates an external clock signal CLK, and a command address control circuit 320 which generates external command signals CMD, an address signal ADD, and a bank address signal BA. The clock generation circuit 310 generates the external signal clock CLK based on a base clock signal BC supplied from outside, and outputs the external signal clock CLK through a buffer circuit 331 and a clock terminal 301. The output external clock signal CLK is supplied to the clock terminal 11 of the semiconductor device 10.

The command address control circuit 320 includes a burst control circuit 321 and a latency control circuit 322. The burst control circuit 321 controls the burst length. The latency control circuit 322 controls a read latency and a write latency. When performing mode register setting on the semiconductor device 10, the command address control circuit 320 acquires a burst length setting code from the burst control circuit 321 and a latency setting code from the latency control circuit 322, and outputs the codes through a buffer circuit 333 and an address terminal 303. A mode register setting command is output through a buffer circuit 332 and a command terminal 302. The address signal ADD output in synchronization with the mode register setting command serves as a mode signal for rewriting the mode register 33 of the semiconductor device 10.

When making the semiconductor device 10 actually perform a read operation and a write operation, the command address control circuit 320 issues the external command signals CMD, and outputs an address signal ADD and a bank address signal BA of the access designation. As a result, the semiconductor device 10 can perform the foregoing read operation and write operation.

Furthermore, in the information processing system 91, a data control circuit 370 is provided. The data control circuit 370 is a circuit that controls the input and output timings of the read data and write data. At the time of a read operation, the data control circuit 370 receives a strobe signal DQS that is input via a terminal 306. At the time of a write operation, the data control circuit 370 outputs the strobe signal DQS via the terminal 306. Therefore, the timings of the read data and write data, which are input into and output from the data processing circuit 360, are controlled by the data control circuit 370.

Data transfer from the semiconductor device 10 to the semiconductor device 300, i.e., a read operation of the semiconductor device 10 will be described. Initially, the semiconductor device 300 supplies the external clock signal CLK to the clock terminal 11 of the semiconductor device 10. In the meantime, the semiconductor device 300 supplies the external command signals CMD serving as a read command to the command terminal 12 of the semiconductor device 10, the address signal ADD serving as a column address to the address terminal 13 of the semiconductor device 10. When the semiconductor device 10 performs the read operation, the read data DQ are burst input to the data terminal 305 of the semiconductor device 300. The read data DQ that are burst input to the data terminal 305 are transferred to the data processing circuit 360 via the input buffer 341.

As described above, in the semiconductor device 10, the output start timing of read data is different between the case where the burst length is two bits and the case where the burst length is four bits. That is, the read latency varies. Therefore, if the burst length that is set in the burst control circuit 321 is two bits, the data control circuit 370 is controlled by a timing that is based on the read latency set in the latency control circuit 322. If the burst length that is set in the burst control circuit 321 is four bits, the data control circuit 370 is controlled by a timing that is obtained by adding one to the read latency set in the latency control circuit 322. Accordingly, even as the read latency of the semiconductor device 10 varies according to the burst length, the read data DQ can be properly received on the side of the semiconductor device 300.

When data is transferred from the semiconductor device 300 to the semiconductor device 10, i.e. when a write operation of the semiconductor device 10 is performed, the semiconductor device 300 supplies a write command as an external command signal CMD to the command terminal 12 of the semiconductor device 10 while supplying an external clock signal CLK to the clock terminal 11 of the semiconductor device 10, and supplies a column address as an address signal ADD to the address terminal 13 of the semiconductor device 10. In the semiconductor device 300, write data are output from the data processing circuit 360. The write data are output from the data terminal 305 via the output buffer 342. As a result, the semiconductor device 10 performs the write operation, which is described in FIG. 4, thereby writing the write data to a predetermined memory cell.

As described above, in the semiconductor device 10, the write latency does not vary according to the burst length. Therefore, in the semiconductor device 300, regardless of the burst length, the period required to start a serial outputting process of a write data set is so set as to be constant.

As described above, the information processing system 91 of the present embodiment uses a control device that is suited for the semiconductor device 10a or 10b of the first or second embodiment. Therefore, it is possible to cope with a change in latency based on the burst length.

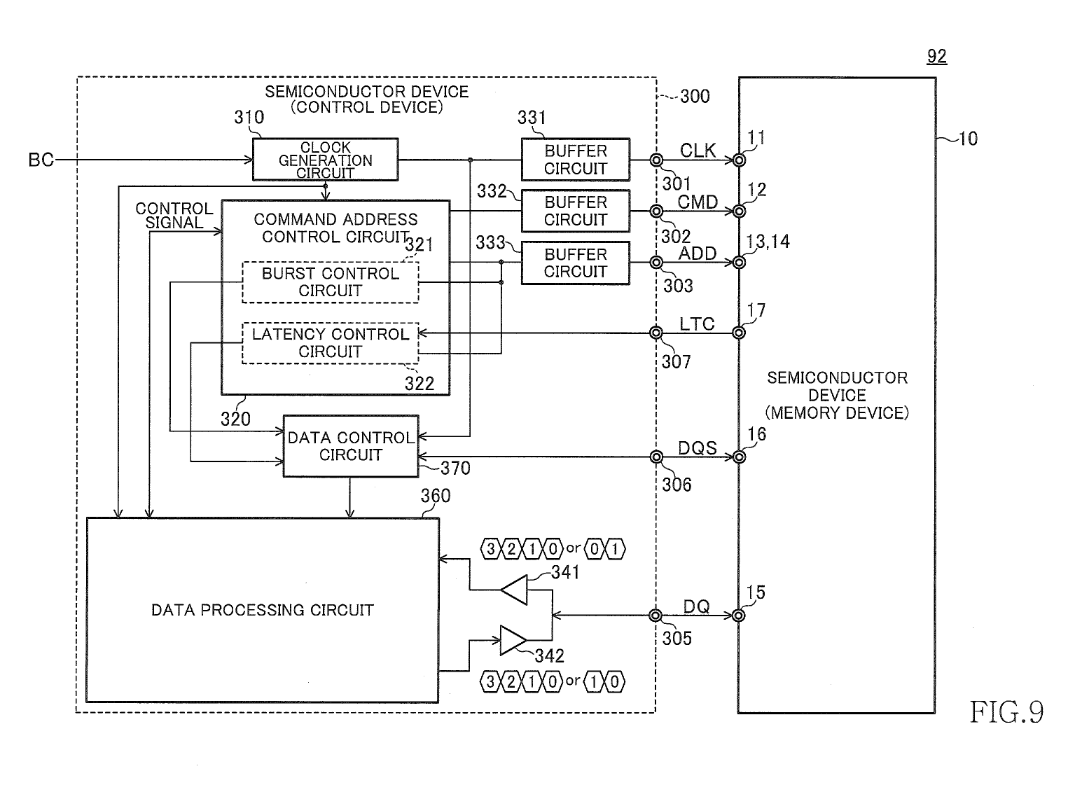

A fourth embodiment of the present invention will be explained with reference to FIG. 9.

The information processing system 92 shown in FIG. 9 is different from the above-described information processing system 91 in that a latency setting flag LTC is supplied from the semiconductor device 10. The latency setting flag LTC is output from a terminal 17 that is provided in the semiconductor device 10. The latency setting flag LTC is supplied to the latency control circuit 322 via a terminal 307 that is provided in the semiconductor device 300. According to the present embodiment, the latency indicated by the latency setting flag LTC is different between the case where the burst length set in the mode register 33 of the semiconductor device 10 is two bits and the case where the burst length is four bits. More specifically, when the burst length set in the mode register 33 of the semiconductor device 10 is four bits, the latency indicated by the latency setting flag LTC is increased by one compared with the case where the burst length is two bits. As a result, the same advantageous effects as those of the information processing system 91 shown in FIG. 8 can be achieved.

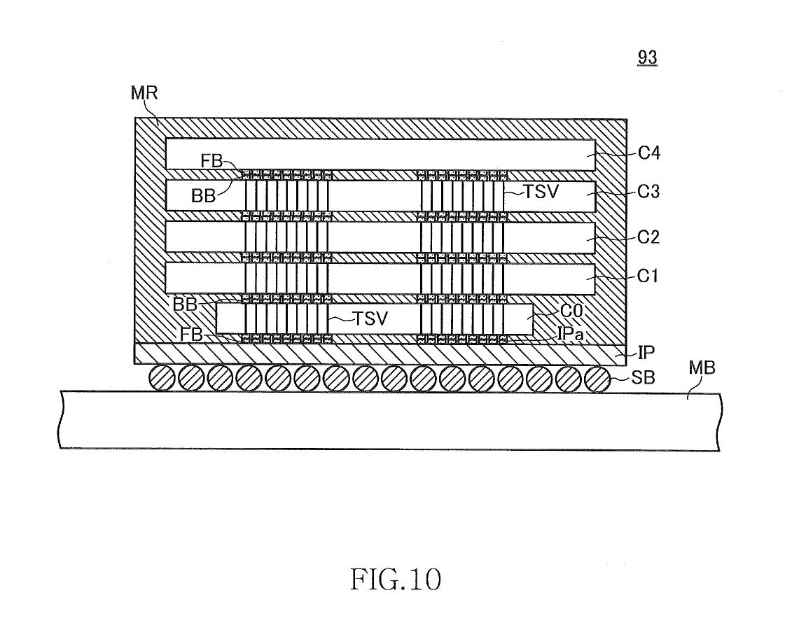

The fifth embodiment of the present invention will be explained with reference to FIG. 10.

The information processing system 93 according to the present embodiment has a structure that a semiconductor chip C0 functioning as a control device and four semiconductor chips C1 to C4 functioning as a memory device are stacked. Each of the semiconductor chips C1 to C4 functions as a DRAM by itself. The semiconductor devices 10a or 10b according to the foregoing first or second embodiments may be used as the semiconductor chips C1 to C4.

The semiconductor chips C0 to C4 are stacked on a package substrate IP by a face-down manner. The face-down manner refers to that the semiconductor chips are mounted so that their main surfaces where transistors and other electronic circuits are formed are directed downward, i.e., toward the package substrate IP. However, the present invention is not limited thereto, and the semiconductor chips may be stacked by a face-up manner. The face-up manner refers to that the semiconductor chips are mounted so that their main surfaces where transistors and other electronic circuits are formed are directed upward, i.e., to the side opposite from the package substrate IP. Some of the semiconductor chips may be stacked by the face-down manner while the other(s) is/are stacked by the face-up manner.

Of the semiconductor chips C0 to C4, the semiconductor chips C0 to C3, except the semiconductor chip C4 lying at the uppermost layer, include a large number of penetrating electrodes TSV which penetrate through the respective silicon substrates. The penetrating electrodes may be called. The penetration electrodes may be called through-electrodes, through-vias, or through-substrate vias. Surface bumps FB are formed on the main surface sides of the chips, and backside bumps BB on the backsides of the chips, at positions overlapping the penetrating electrodes TSV when seen in a plan view taken in the stacking direction. The backside bumps BB of semiconductor chips lying in lower layers are joined to the surface bumps FB of semiconductor chips lying in upper layers, whereby the vertically-adjoining semiconductor chips are electrically connected to each other.

In the present embodiment, the semiconductor chip C4 at the uppermost layer includes no penetrating electrode TSV. The reason is that the semiconductor chip C4 needs no bump electrode on the backside due to the face-down stacking. Without a penetrating electrode TSV, the semiconductor chip C4 at the uppermost layer can be made thicker than the other semiconductor chips C0 to C3. This can increase the mechanical strength of the semiconductor chip C4. Note that according to the present invention, the semiconductor chip C4 at the uppermost layer may include penetrating electrodes TSV. In such a case, the semiconductor chips C1 to C4 can be manufactured by the same processes.

With such a configuration, an external clock signal CLK, external command signals CMD, an address signal ADD, a bank address signal BA, write data DQ, and the like output from the semiconductor chip C0 functioning as a control device are supplied to the four semiconductor chips C1 to C4 in common. Read data DQ to be supplied from the semiconductor chips C1 to C4 to the semiconductor chip C0 is wired-ORed and input into the semiconductor chip C0. It should be noted that the data path need not necessarily be connected to all the semiconductor chips C1 to C4 in common. The semiconductor chips C1 to C4 may be individually connected to the semiconductor chip C0. The semiconductor chips C1 and C2 may form a common data path while the semiconductor chips C3 and C4 form a common path.

The surface bumps FB of the semiconductor chip C0 are connected to substrate electrodes IPa formed on the package substrate IP, and connected to solder balls SB on the backside through wiring on the package substrate IP and inside the package substrate IP. The package substrate IP and the semiconductor chips C0 to C4 are sealed with molding resin MR to constitute a multichip package.

The information processing system 93 (multichip package) having such a configuration is mounted on a wiring substrate MB such as a motherboard. Other semiconductor chips, such as a MPU and a CPU, and electronic parts are also mounted on the wiring substrate MB. Since the package substrate IP includes an insulator and conductors on the surface or inside of the insulator, the package substrate IP may be regarded as a kind of printed circuit board.

The foregoing fifth embodiment of the present invention has dealt with an example where the semiconductor chips C1 to C4 each include any one of the semiconductor devices 10a or 10b according to the foregoing first or second embodiments, i.e., a chip that functions as a so-called DRAM by itself. However, according to the present invention, the number of semiconductor devices 10a or 10b included in each of the semiconductor chips C1 to C4 is not limited to one. More specifically, the semiconductor chips C1 to C4 each may include a plurality of semiconductor devices 10a or 10b that function as a so-called DRAM by themselves. Similarly, the semiconductor chip C0 may be a semiconductor chip including a plurality of control devices.

It is apparent that the present invention is not limited to the above embodiments, but may be modified and changed without departing from the scope and spirit of the invention.

For example, in the semiconductor device 10a or 10b of the first or second embodiment, the strobe signal DQS is used for the input and output timings of the read data and write data. However, according to the present invention, the use of the strobe signal DQS is not necessarily required. If the strobe signal DQS is not used, the control device may capture the read data in synchronization with the external clock signal CLK; the memory device may capture the write data in synchronization with the internal clock signal CLKI.

In the semiconductor device 10a or 10b of the first or second embodiment, the difference between the period TR1 and the period TR2 is set to one clock cycle. However, the present invention is not limited to one clock cycle. For example, if the frequency of the external clock signal CLK is higher, the difference between the period TR1 and the period TR2 may be so set as to be longer than the period from the time when a process of outputting a certain read data set starts until the time when the process of outputting the read data set is finished. In this case, the read data can be seamlessly output in bursts. The same is true for the difference between the period TR1 and the period TR3, and the difference between the period TW1 and the period TW2: if the frequency of the external clock signal CLK is higher, the differences may be set larger than in the above embodiments.

What is claimed is:

1. A semiconductor device comprising:
a command terminal configured to receive a read command;
a data terminal;
a plurality of memory banks;
a data interconnection coupled in common to the memory banks;
a control circuit configured to respond to the read command to perform a first read operation in which first and second read data sets are serially transferred from one of the memory banks to the data interconnection, each of the first and second read data sets including a plurality of read data, the first and second data sets appearing on the data interconnection respectively at first and second timings; and
an output circuit configured to receive the first and second data sets from the data interconnection, to start outputting the first read data set to the data terminal at a third timing and to start outputting the second read data set to the data terminal at a fourth timing, a first period of time intervening between the first and third timings, a second period of time intervening the second and fourth timings, the second period of time being different from the first period of time.

2. The semiconductor device as claimed in claim 1, wherein the first period of time is longer than the second period of time.

3. The semiconductor device as claimed in claim 2, wherein the output circuit is configured to finish outputting the first read data set at a fifth timing, and a difference between the first period of time and the second period of time is greater than or equal to a third period of time from the third timing to the fifth timing.

4. The semiconductor device as claimed in claim 3, wherein the difference between the first period of time and the second period of time is substantially equal to the third period of time.

5. The semiconductor device as claimed in claim 1, wherein the output circuit is configured to output the first and second read data sets in series at a first interval and output the read data in each of the first and second read data sets in series at a second interval, and the first and second intervals are substantially equal in time to each other.

6. The semiconductor device as claimed in claim 1, wherein the control circuit, in a first operation mode, is configured to respond to the read command to perform the first read operation, and the control circuit, in a second operation mode, is configured to respond to the read command to perform a second read operation in which the first read data set is transferred from the one of the memory banks to the data interconnection without being followed by the second read data set.

7. The semiconductor device as claimed in claim 6, wherein the output circuit, in the first operation mode, is configured to start outputting the first read data set to the data terminal at the third timing, and the output circuit, in the second operation mode, is configured to start outputting the first read data set to the output terminal at fifth timing, the third period of time intervenes between the first and fifth timings, and the third period of time is different from the first period of time.

8. The semiconductor device as claimed in claim 7, wherein the first period of time is greater than the third period of time.

9. The semiconductor device as claimed in claim 8, wherein the output circuit is configured to finish outputting the first data set at a sixth timing, and a difference between the first period and the third period of time is greater than or equal to a fourth period of time from one of the first and the third timings to the sixth timing.

10. The semiconductor device as claimed in claim 9, wherein the difference between the first period of time and the third period of time is substantially equal to the fourth period of time.

11. The semiconductor device as claimed in claim 1, wherein the semiconductor device is configured to be externally supplied a write request including a write command and first and second write data sets, each of the first and second write data sets includes a plurality of write data, and
the semiconductor device further comprises an input circuit configured to start receiving the first data set at a fifth timing and the second write data set at a sixth timing following the fifth timing, the input circuit further configured to supply the data interconnection with the first write data set at seventh timing and the second write data set and second write data sets at eighth timing following the seventh timing,
wherein a third period of time intervenes between the fifth and seventh timings, a fourth period of time intervenes between the sixth and eighth timings, and the fourth period of time is different from the third period of time.

12. The semiconductor device as claimed in claim 11, wherein the third period of time is shorter than the fourth period of time.

13. The semiconductor device as claimed in claim 12, wherein the input circuit is configured to finish receiving the first write data set at a ninth timing, and a difference between the third period of time and the fourth period of time is greater than or equal to a fifth period of time from the fifth timing to the ninth timing.

14. The semiconductor device as claimed in claim 13, wherein the difference between the third period of time and the fourth period of time is substantially equal to the fifth period of time.

15. A device comprising:
a data terminal;
a plurality of memory banks; and
a control circuit configured to control a data transfer between the data terminal and the memory banks, the control circuit being configured to set a read latency in response to a burst length.

16. The device as claimed in claim 15, wherein the control circuit is configured to set a write latency independently of the burst length.

17. The device as claimed in claim 15, wherein the control circuit is configured to set the read latency to a first value when the burst length is a first length and to set the read latency to a second value when the burst length is a second length, the first value is greater than the second value, and the first length is greater than the second length.

18. The device as claimed in claim 15, further comprises a mode register circuit that stores the read latency and the burst length information.

19. The device as claimed in claim 18, further comprises a first terminal, and wherein the mode register is configured to supply the first terminal with a latency information signal that indicates the read latency.

20. The device as claimed in claim 16, further comprises a command terminal configured to receive a read command and a first terminal configured to receive a burst length information that supplied the device along with the read command, wherein the burst length information is indicative of the burst length.
